(19) United States
(12) Patent Application Publication
(10) Pub. No.: US 2019/0134651 A1
(43) Pub. Date: May 9, 2019

(54) SYSTEM AND METHOD OF FORMING SELENIZED COMPOSITE METAL POWDER

(71) Applicant: BEIJING APOLLO DING RONG SOLAR TECHNOLOGY CO., LTD., Beijing (CN)

(72) Inventors: Robert Jeffrey BAILEY, Scotts Valley, CA (US); Geordie ZAPALAC, Santa Clara, CA (US)

(21) Appl. No.: 15/807,245

(22) Filed: Nov. 8, 2017

(51) Int. Cl. B05B 1/00; C01B 19/00; B01D 5/00; B05B 1/02; H01L 31/0272

(52) U.S. Cl. CPC B05B 1/005; C01B 19/002; B01D 5/0081; H01L 31/0272; B01D 5/0051; B05B 1/02; B01D 5/0093

(57) ABSTRACT

A method includes providing a molten stream of a metal material to an atomizer, atomizing the molten stream using at least one jet of a vapor stream comprising a selenium vapor to form atomized droplets, and solidifying the atomized droplets to form selenized metal particles.

The present disclosure is directed generally to an apparatus and method of forming a selenized metal powder, and particularly to an apparatus and method for forming selenized copper indium gallium (CIG) powder using selenium vapor.

### BACKGROUND

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (CIGS).

Thin-film photovoltaic cells (also known as photovoltaic cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

### SUMMARY

According to various embodiments of the present disclosure, a system for forming selenized metal powder particles includes a collection chamber configured to receive a molten stream of a metal material, an atomizer containing at least one nozzle, wherein the atomizer is disposed within or above the collection chamber, a selenium vapor source, and a carrier gas source configured to provide a carrier gas stream through the selenium vapor source to the atomizer The atomizer is configured to emit at least one jet of a vapor stream comprising the carrier gas and the selenium vapor that impinges upon the molten stream to atomize the molten stream.

According to another aspect of the present disclosure, a method includes providing a molten stream of a metal material to an atomizer, atomizing the molten stream using at least one jet of a vapor stream comprising a selenium vapor to form atomized droplets, and solidifying the atomized droplets to form selenized metal particles.

### BRIEF DESCRIPTION OF THE DRAWINGS

FIG. 1A is a schematic vertical cross-sectional view of a system for forming a selenized composite metal powder, according to various embodiments of the present disclosure.

FIG. 1B is a vertical cross-sectional view along line B-B′ in FIG. 1C of the manifold and selenium vapor source of the system of FIG. 1A.

FIG. 1C is a top plan view of a manifold of the system of FIG. 1A

FIG. 2 is a block diagram depicting a method of forming a selenized metal powder, according to various embodiments of the present disclosure.

FIG. 3A is a schematic cross-sectional view of a planar sputtering target, according to various embodiments of the present disclosure.

FIG. 3B is a perspective view of a tubular sputtering target, according to various embodiments of the present disclosure.

FIG. 4 is a schematic cross-sectional view of a thin-film photovoltaic cell, according to various embodiments of the present disclosure.

### DETAILED DESCRIPTION

As set forth herein, various aspects of the disclosure are described with reference to the exemplary embodiments and/or the accompanying drawings in which exemplary embodiments of the invention are illustrated. This invention may, however, be embodied in many different forms and should not be construed as limited to the exemplary embodiments shown in the drawings or described herein. It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It will also be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Ranges may be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. In some embodiments, a value of “about X” may include values of +/−1% X. It will be further understood that the endpoints of each of the ranges are significant both in relation to the other endpoint, and independently of the other endpoint. Herein, “substantially all” of an element may refer to an amount of the element ranging from 98-100% of the total amount of the element. In addition, when a component is referred to as being “substantially free” of an element, the component may be completely free of the element or may include a trace amount (e.g., 1% or less) of the element.

Chalcogen-containing compound semiconductor materials, such copper indium gallium selenide (“CIGS”) have been recognized as effective p-type solar cell absorber layer materials for the production of high efficiency, low cost, thin-film solar cells. CIGS is a compound with a chemical formula of CuInₓGa₍₁₋ₓ₎Se₂, where the value of x can vary from 1 (pure copper indium selenide) to 0 (pure copper gallium selenide). Preferably, CIGS contains both indium and gallium. A CIGS absorber layer of a solar cell may be formed by reactive sputtering of a copper, copper indium, copper gallium and/or copper indium gallium (“CIG”) sputtering targets in a selenium containing ambient, such as selenium gas or hydrogen selenide gas.

The formation of copper, copper indium, copper gallium and/or CIG powder for use in sputtering target fabrication my include atomization of a stream of molten metal material, such as a pure metal (e.g., copper) or metal alloy (e.g., copper indium, copper gallium and/or CIG) material. In particular, the stream of molten (i.e., liquid) metal material may interact with impinging gas jets to disperse the stream into liquid droplets. The droplets are then solidified to form the metal (e.g., pure metal or metal alloy) powder particles. In one embodiment of the present disclosure, the gas jets may include selenium vapor to intentionally form a thin selenium containing layer on the surface of the powder particles (i.e., to form selenized metal powder particles). Without wishing to be bound by a particular theory, the present inventors believe that the selenium containing layers improve the handling properties of the resultant powder by reducing the “stickiness” of powder particles. For example, it is believed that the selenium containing layer reduces or prevents agglomeration of the particles by reducing or preventing to metal-to-metal particle contact.

The selenized metal powder, such as a selenized CIG powder may be used as the source powder to form metal sputtering targets, such as CIG sputtering targets used for reactive sputtering of CIGS absorber layer for a solar cell. Since the CIGS absorber layer is a selenium containing selenide layer, the selenium contained in the powder used to form the target is a desired component of the final absorber layer and not an unwanted impurity which must be removed prior to solar cell formation. Therefore, the selenium in the selenized metal powder does not have to be subsequently removed, and can be incorporated into the sputtering target and then into the resulting CIGS absorber layer formed by reactive sputtering.

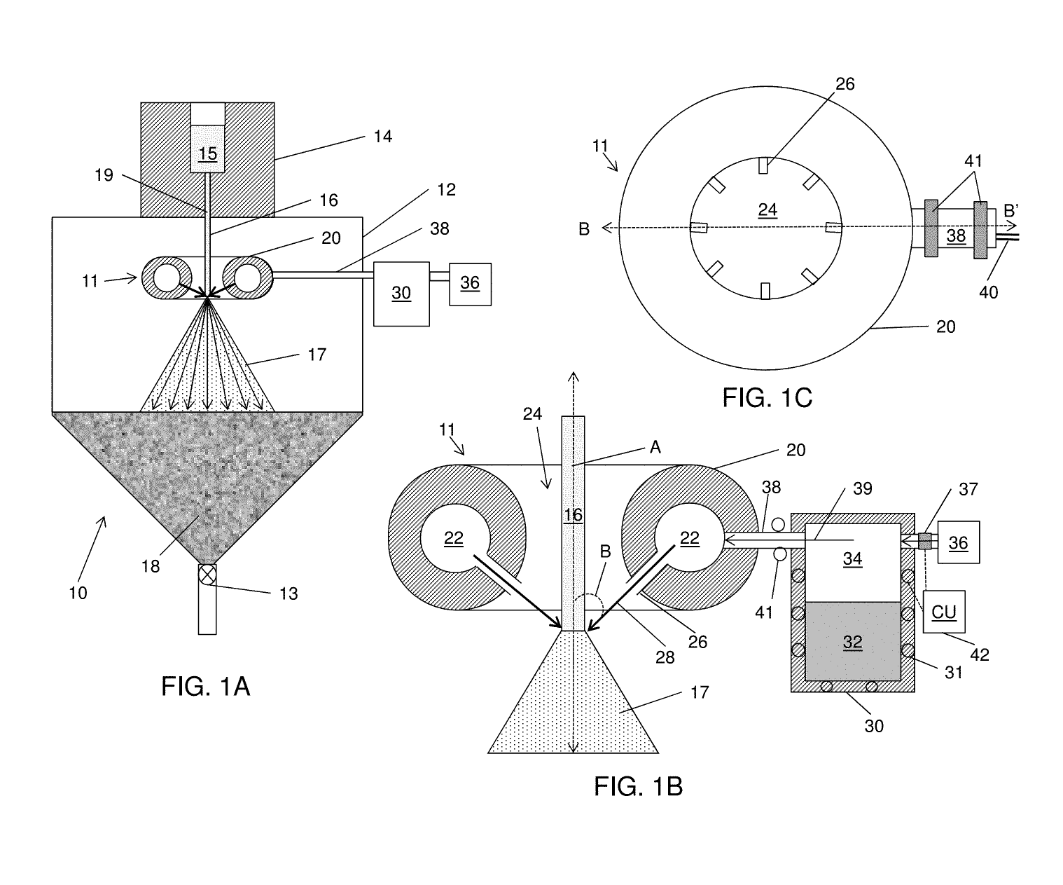

FIG. 1A is a vertical cross-sectional view of a system 10 for generating a selenized composite powder, according to various embodiments of the present disclosure. FIG. 1B is a vertical cross-sectional view of a manifold 20 of FIG. 1A, and FIG. 1C is a top plan view of the manifold 20.

Referring to FIGS. 1A-1C, the system 10 includes an atomizer 11, a collection chamber 12, a crucible (i.e., a molten metal holding vessel) 14 disposed adjacent to the collection chamber 12, and a selenium vapor source 30 connected to the atomizer 11. In one embodiment, the atomizer 11 comprises a manifold 20 disposed above or within the collection chamber 12. The collection chamber 12 may be configured to maintain a partial vacuum and/or may be configured to contain a substantially oxygen-free atmosphere. The collection chamber 12 may include a valve or door 13 configured to control the release of powder collected in the collection chamber 12.

The crucible 14 may be configured to melt a metallic material 15, such as a pure metal or metal alloy (e.g., CIG or an alloy containing at least 90% by weight of CIG). In various embodiments, the metallic material 15 includes copper, indium, and gallium, or an alloy thereof. The crucible 14 may be configured to heat the metallic material 15 to a temperature of from about 50° C. to about 200° C. higher than the melting point of the metallic material 15. In some embodiments, the temperature may be based on the melting point of a component of the metallic material 15 having the highest melting point.

The crucible 14 may be configured to provide a molten stream 16 of the metallic material 15 to the collection chamber 12. For example, the crucible 14 may be configured to provide the molten stream 16 to an upper end of the collection chamber 12, such that the molten stream 16 flows vertically downward through an opening (e.g., nozzle) 19 in the crucible 14 into the collection chamber 12.

The manifold 20 may be disposed in the collection chamber 12 so as to receive the molten stream 16. The manifold 20 may include an internal chamber 22, a central opening 24 configured to receive the molten stream 16, and nozzles 26 fluidly connected to the internal chamber 22. The internal chamber 22 may be fluidly connected to the vapor source 30 by one or more distribution conduits 38. The manifold 20 may be configured to atomize the molten stream 16 and thereby form droplets 17, as discussed in detail below. The droplets 17 may cool and settle as powder particles 18 at the bottom of the collection chamber 12. The powder particles 18 are then removed from the collection chamber 12 through the valve or door 13. The collection chamber 12 may be filled with an inert gas atmosphere, such as argon or nitrogen atmosphere.

According to various embodiments, the manifold 20 may be generally annular in shape to minimize friction losses. However, the manifold 20 is not limited to any particular shape. The manifold 20 is shown to include eight nozzles 26. However, the manifold 20 may include any suitable number of nozzles 26, such as one to twenty nozzles.

In various embodiments, the vapor source 30 may be an evaporator or furnace which includes heating elements 31, such as resistive heating elements. The heating elements 31 may be configured to vaporize selenium 32 located in the vapor source. The heating elements 31 of the vapor source 30 may be configured to heat the selenium 32 such that the selenium 32 is liquefied, which produces a saturation vapor pressure in a headspace 34 of the vapor source 30 disposed above the selenium 32. The vapor source 30 may be fluidly connected to a carrier gas source 36 (e.g., a gas pipe and/or a gas storage vessel) configured to provide a carrier gas to the headspace 34, such that a vapor stream 39 including the selenium vapor and the carrier gas is carried into one or more distribution conduits 38.

The carrier gas may be an inert gas, such as nitrogen (N₂), noble gas (e.g., argon), combinations thereof, or the like. The vapor source 30 may also include a mass flow meter 37 configured to control the flow rate of the carrier gas.

In operation, the carrier gas provided by the gas source 36 mixes with the selenium vapor from the headspace 34 to form the vapor stream 39, and the vapor stream 39 flows into the internal chamber 22 of the manifold 20, via the distribution conduit 38. The internal chamber 22 is configured to provide the vapor stream 39 to the nozzles 26. The nozzles 26 are configured to emit jets 28 of the vapor stream 39 that impinge upon the molten stream 16. Generally, the nozzles 26 may be configured such that lengthwise axes of the nozzles 26 and corresponding jets 28 intersect at one or more points in the molten stream 16. The one or more points may be disposed on a vertical axis A that extends through the center of the opening 24 and along which the molten stream 16 flows, as shown in FIG. 1B.

The jets 28 may be configured to atomize the molten stream 16 into droplets 17. The initially liquid droplets 17 cool and solidify, and then settle as powder particles 18 at the bottom of the collection chamber 12. Without wishing to be bound by a particular theory, it is believed that during the atomization and/or solidification, the droplets 17 react with the selenium vapor included in the jets 28, forming a thin selenium-containing coating on the powder particles 18. The selenium-containing coating may operate to prevent agglomeration and/or improve handling characteristics of the powder particles 18. In some embodiments, the selenium-containing coating may be formed entirely or substantially of selenium. In other embodiments, the selenium-containing coating may include selenium mixed, alloyed or reacted with other elements of the powder particles 18. For example, selenized CIG powder particles can contain a CIGS coating around CIG metal alloy powder particles 18.

The nozzles 26 may be vertically and horizontally adjustable. The nozzles 26 may be configured to form substantially flat jets 28 to improve control of the size and shape of generated particles. However, other spray jet shapes may be employed. The nozzles 26 may be aligned such that the jets 28 form an acute angle B with respect to the vertical axis A, as shown in FIG. 1B. For example, angle B may range from about 30 to 60 degrees.

The system 10 may also include temperature control elements disposed in, on and/or adjacent to the conduit 38. The temperature control elements may include temperature sensors 40, such as thermocouples, and heating elements 41, such as resistive heaters. The heating elements 41 may be configured to maintain the temperature of the conduit 38 and/or the temperature of the manifold 20 at a temperature that prevents or substantially prevents condensation of the vapor stream 39. In one embodiment, the temperature of the heating elements 41 may be higher than the temperature of the heating elements 31 such that the temperature in the conduit 38 is higher than the temperature in the vapor source 30. In some embodiments, the manifold 20, the conduit 38, and/or the vapor source 30 may be thermally insulated to reduce heat loss.

The system 10 may include a control unit 42 configured to control the atomization of the molten stream 16 and the selenization of the powder particles 18. For example, control unit 42 may be a central processing unit or the like (e.g., computer) configured to control the average powder particle size, the shape of a resultant powder particles 18 and/or the degree of selenization of the powder particles 18. The flow rate of the jets 28 emitted from the nozzles 26 may be controlled by the control unit 42 by controlling the mass flow meter 37 to control the flow rate of the carrier gas provided from the carrier gas source 36. The degree of selenization may be controlled by the control unit 42 by controlling the temperature of the heating elements 31 to control the temperature of the selenium 32 in the vapor source 30. In particular, the vapor pressure of the selenium in the headspace 34 is a function of the temperature of the selenium 32. As such, the vapor pressure may be controlled by controlling the temperature of the selenium 32.

Thus, in one embodiment, a system 10 for forming selenized metal powder particles includes a collection chamber 12 configured to receive a molten stream 16 of a metal material, an atomizer 11 containing at least one nozzle 26, wherein the atomizer 11 is disposed within or above the collection chamber 12, a selenium vapor source 30, and a carrier gas source 36 configured to provide a carrier gas stream through the selenium vapor source 30 to the atomizer 11. The atomizer 11 is configured to emit at least one jet 28 of a vapor stream comprising the carrier gas and the selenium vapor that impinges upon the molten stream 16 to atomize the molten stream.

In one embodiment, the metal material comprises a copper indium gallium (CIG) alloy, the collection chamber 12 is configured to receive CIG droplets 17 from the atomizer 11 and to cool and solidify the CIG droplets 17 to form CIG powder particles 18, the at least one nozzle comprises a plurality of nozzles 26. In one embodiment, the atomizer 11 comprises a manifold 20 containing the plurality of nozzles 26 which are configured to direct the jets 28 of the vapor stream into the molten stream 16 such that the selenium vapor reacts with CIG powder particles 18 and forms a selenium-containing coating on the CIG powder particles 18.

In one embodiment, the manifold 20 comprises an opening 24 configured to receive the molten stream 16, an annular internal chamber 22 surrounding the opening 24 and configured to receive the vapor stream 39 from the selenium vapor source 30, and the plurality of nozzles 26 fluidly connected to the internal chamber 22 and configured to form the jets 28 of the vapor stream. In one embodiment, the plurality of nozzles 26 are configured to direct the jets 28 toward the molten stream 16 at an acute angle “B” with respect to a flow direction “A” of the molten stream, as shown in FIG. 1B.

In one embodiment, the selenium vapor source 30 comprises a furnace or evaporator which is configured to heat selenium 32 to generate selenium vapor in a headspace 34 above the heated selenium 32. The selenium vapor source 30 is configured to receive the carrier gas from the carrier gas source 36 fluidly connected to the headspace 34. In one embodiment, at least one distribution conduit 38 fluidly connects the headspace 34 of the selenium vapor source 30 to the annular internal chamber 22 of the manifold 20.

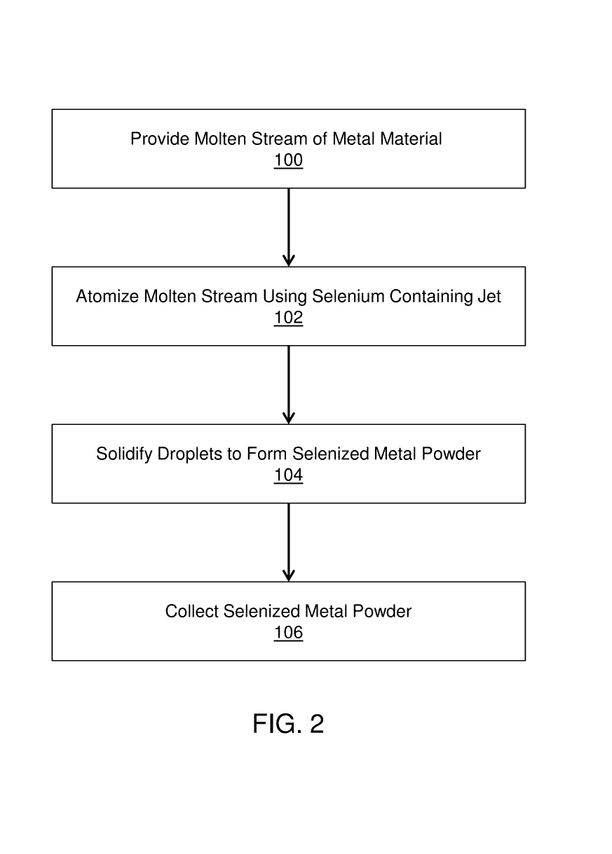

FIG. 2 is a block diagram illustrating a method of forming a metal powder using the system 10, according to various embodiments of the present disclosure. Referring to FIGS. 1A, 1B, 1C and 2, in step 100, the method includes providing the molten stream 16 of a metal material, such as a CIG material for example. The molten stream 16 may be provided from the opening 19 of the crucible 14 into the opening 24 of the manifold 20, as described above.

In step 102, the molten stream 16 is atomized using the selenium containing jets 28 in or below the opening 24 in the manifold 20 (i.e., in or below the atomizer). In particular, the flow of the carrier gas from the carrier gas source 36 is controlled such that the jets 28 of the vapor stream 39 are provided from the nozzles 26 of the atomizer (e g , manifold 20) into the molten stream 16. The jets 28 apply shear forces to the molten stream 16, such that the molten stream 16 is atomized into droplets 17.

In step 104, the droplets 17 are solidified to form selenized metal powder particles 18 (e.g., selenized CIG powder particles). For example, as the droplets 17 cool and solidify, the selenium vapor may react with the CIG material at the surface of the droplets 17 and/or the surface of the powder particles 18 to form the selenium containing coating on the powder particles.

In step 106, the selenized metal powder particles 18 are collected by opening a valve or door 13 at the bottom of the collection chamber 12. In one embodiment, CIG powder particles have a composition of about 29-39 wt % copper, about 49-62 wt % indium, and about 8-16 wt % gallium. Alternatively, the CIG powder particles have a composition of about 8-15 wt % copper, about 55-80 wt % indium, and about 10-25 wt % gallium. CIG alloys may have a Cu—In ratio within a range of 0.66 to 1.50.

According to various embodiments, the powder particles 18 may be used to form a sputtering target, using various methods as discussed above. For example, the powder particles 18 may be used to form a planar sputtering target or a tubular sputtering target. In one embodiment, a CIG sputtering target has a composition of about 29-39 wt % copper, about 49-62 wt % indium, and about 8-16 wt % gallium. Alternatively or in addition, another CIG sputtering target has a composition of about 8-15 wt % copper, about 55-80 wt % indium, and about 10-25 wt % gallium. CIG alloys may have a Cu—In ratio within a range of 0.66 to 1.50.

A solidification temperature range for such alloys is relatively wide, with a high temperature of 660° C., and temperatures decreasing until a solidus temperature of 306° C. is reached. In view of the solidification temperature range, CIG sputtering targets may be formed by cold spraying a CIG powder onto a backing material of a sputtering target, as described in U.S. Pat. No. 9,352,342, which is incorporated herein in its entirety, by reference. In a cold spraying method, the CIG powder is provided into a gas jet which is incident on the backing material or barrier layer surface to form the CIG sputtering layer.

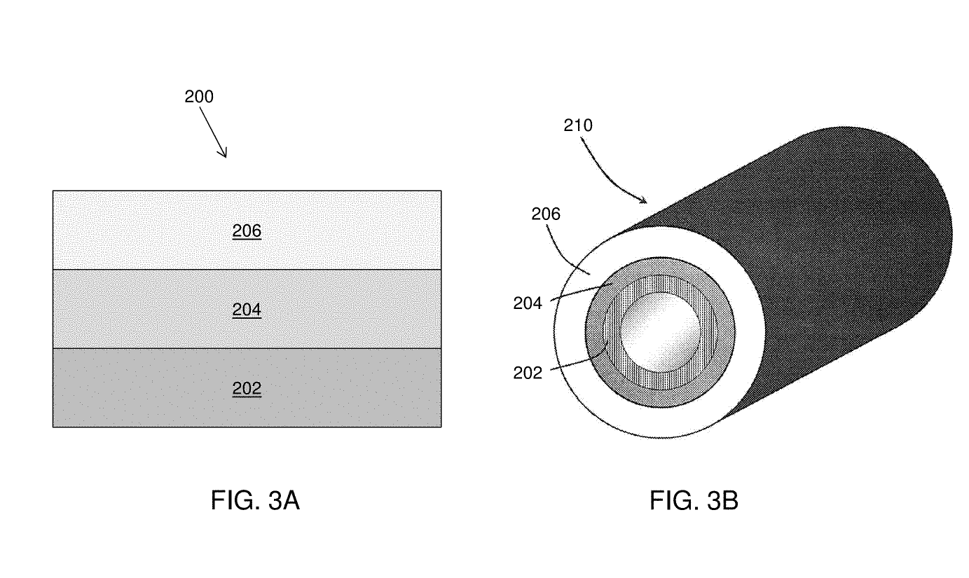

FIG. 3A illustrates a planar sputtering target 200, according to various embodiments of the present disclosure. FIG. 3B illustrates a tubular sputtering target 210, according to various embodiments of the present disclosure.

Referring to FIGS. 3A and 3B, the sputtering target 200 or 210 each includes a backing structure 202, an optional barrier layer 204, and a sputtering layer 206. The sputtering layer may be formed of the selenized CIG powder generated by the system 10. The backing structure 202 may be a plate (FIG. 3A) or tube (FIG. 3B) formed of a material comprising Fe, Ni and/or Cr, such as stainless steel.

The barrier layer 204 may comprise one or more layers of Mo, W, Ta, V, Ti, Nb, Zr, alloys thereof and nitrides thereof. For example, the barrier layer 204 may comprise a first barrier layer comprising Cr formed directly on and in contact with the backing structure 202, and a second barrier layer comprising Mo.

In one embodiment, the selenized CIG powder particles 18 are collected from the collection chamber 12 and provided to a sputtering target 200 or 210 to form a selenized CIG sputtering layer 206 of the sputtering target 200 or 210. The selenized CIG powder particles 18 can be provided to the sputtering target 200 or 210 by cold spraying the selenized CIG powder particles 18 over the backing structure 202 of the sputtering target to form the selenized CIG sputtering layer 206 of the sputtering target 200 or 210.

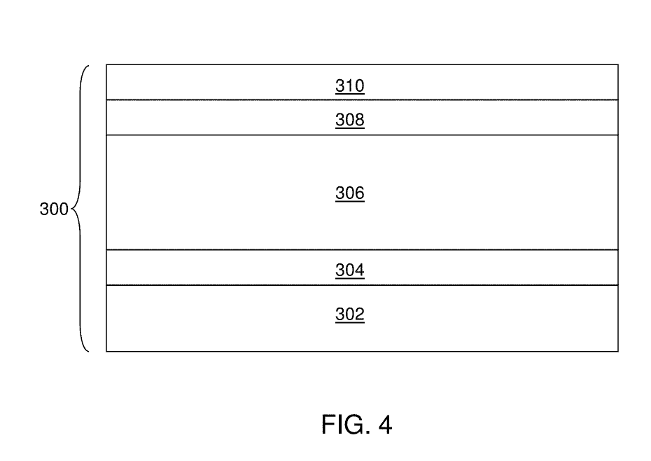

FIG. 4 is a plan view of a solar cell 300 including an absorber layer that may be formed using the sputtering targets 200 or 210. Referring to FIG. 4, the solar cell 300 may include an electrically conductive substrate 302, a first electrode 304, a p-doped semiconductor absorber layer 306, an n-doped semiconductor layer 308, a second electrode 310, and an optional antireflective (AR) coating layer (not shown). These components may be deposited on the substrate 302 as layers by sputtering. However, some layers may be deposited by MBE, CVD, evaporation, plating, nanoparticle or CIG(S) ink-based deposition methods, etc.

The substrate 302 is preferably a flexible, electrically conductive material, such as a metallic foil that is fed into a system of one or more process modules as a web for deposition of additional layers thereupon. For example, the metallic foil of the conductive substrate 302 can be a sheet of a metal or a metallic alloy such as stainless steel, aluminum, or titanium. If the substrate 302 is electrically conductive, then it may comprise a part of the back side (i.e., first) electrode of the cell 300. Thus, the first (back side) electrode of the cell 300 may be designated as (302, 304). Alternatively, the conductive substrate 302 may be an electrically conductive or insulating polymer foil. Still alternatively, the substrate 302 may be a stack of a polymer foil and a metallic foil. In another embodiment, the substrate 302 may be a rigid glass substrate or a flexible glass substrate. The thickness of the substrate 302 can be in a range from 100 microns to 2 mm, although lesser and greater thicknesses can also be employed.

The first or back side electrode 304 may comprise any suitable electrically conductive layer or stack of layers. For example, electrode 304 may include a metal layer, which may be, for example, molybdenum. Alternatively, a stack of molybdenum and sodium and/or oxygen containing molybdenum layers may be used instead, as described in U.S. Pat. No. 8,134,069, which is incorporated herein by reference in its entirety. 4The electrode 304 can have a thickness in a range from 500 nm to 1 micron, although lesser and greater thicknesses can also be employed.

The p-doped semiconductor layer 306 (e.g., absorber layer) can include a p-type sodium doped copper indium gallium selenide (CIGS). The p-doped semiconductor layer may be formed by reactively sputtering one of the targets described herein in a selenium containing ambient (e.g., evaporated selenium). For example, the method may include reactively sputtering the selenized CIG sputtering layer 206 of the sputtering target 200 or 210 in a selenium containing ambient to form a copper indium gallium selenide absorber layer 306 of a solar cell 300.

The thickness of the p-doped semiconductor layer 306 can be in a range from 1 microns to 5 microns, although lesser and greater thicknesses can also be employed. The absorber layer 306 may be formed by reactively sputtering several CIGS sublayers containing different ratios of copper to Group III metal using sequentially placed targets having CIG sputtering layers with different ratios of copper to Group III metal.

The n-doped semiconductor layer 308 includes an n-doped semiconductor material such as CdS, ZnS, ZnSe, or an another metal sulfide or a metal selenide. The thickness of the n-doped semiconductor layer 308 is typically less than the thickness of the p-doped semiconductor layer 306, and can be in a range from 1 nm to 100 nm, although lesser and greater thicknesses can also be employed. The junction between the p-doped semiconductor layer 306 and the n-doped semiconductor layer 308 is a p-n junction. The n-doped semiconductor layer 308 can be a material which is substantially transparent to at least part of the solar radiation. The n-doped semiconductor layer 308 is also referred to as a window layer or a buffer layer.

The second (e.g., front side or top) electrode 310 comprises one or more transparent conductive layers 310. The transparent conductive layer 310 is conductive and substantially transparent. The transparent conductive layer 310 can include one or more transparent conductive materials, such as ZnO, indium tin oxide (ITO), Al doped ZnO (“AZO”), Boron doped ZnO (“BZO”), or a combination or stack of higher resistivity AZO and lower resistivity ZnO, ITO, AZO and/or BZO layers. The second electrode 310 contacts an electrically conductive part (e.g., a metal wire or trace) of an interconnect, such as an interconnect described in U.S. Pat. No. 8,912,429, issued Dec. 16, 2014, which is incorporated herein by reference in its entirety, or any other suitable interconnect that is used in photovoltaic panels.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the present invention.

What is claimed is:

1. A system for forming selenized metal powder particles, the system comprising:
a collection chamber configured to receive a molten stream of a metal material;
an atomizer containing at least one nozzle, wherein the atomizer is disposed within or above the collection chamber;
a selenium vapor source; and
a carrier gas source configured to provide a carrier gas stream through the selenium vapor source to the atomizer;
wherein the atomizer is configured to emit at least one jet of a vapor stream comprising the carrier gas and the selenium vapor that impinges upon the molten stream to atomize the molten stream.

2. The system of claim 1, wherein:
the metal material comprises a copper indium gallium (CIG) alloy;
the collection chamber is configured to receive CIG droplets from the atomizer and to cool and solidify the CIG droplets to form CIG powder particles;
the at least one nozzle comprises a plurality of nozzles and the at least one jet comprises a plurality of jets; and
the atomizer comprises a manifold containing the plurality of nozzles which are configured to direct jets of the vapor stream into the molten stream such that the selenium vapor reacts with CIG powder particles and forms a selenium-containing coating on the CIG powder particles.

3. The system of claim 2, wherein the manifold comprises:
an opening configured to receive the molten stream;
an annular internal chamber surrounding the opening and configured to receive the vapor stream from the selenium vapor source; and
the plurality of nozzles fluidly connected to the internal chamber and configured to form the plurality of jets of the vapor stream.

4. The system of claim 3, wherein:
the selenium vapor source comprises a furnace or evaporator which is configured to heat selenium to generate the selenium vapor in a headspace above the heated selenium; and
the selenium vapor source is configured to receive the carrier gas from the carrier gas source fluidly connected to the headspace.

5. The system of claim 4, wherein the plurality of nozzles are configured to direct the plurality of jets toward the molten stream at an acute angle with respect to a flow direction of the molten stream.

6. The system of claim 4, further comprising:
a crucible configured to provide the molten stream; and
at least one distribution conduit fluidly connecting the headspace of the selenium vapor source to the annular internal chamber of the manifold.

7. The system of claim 6, further comprising at least one temperature control element configured to maintain a temperature of the at least one distribution conduit, the manifold, or both the at least one distribution conduit and the manifold at a temperature that prevents the selenium vapor from condensing.

8. The system of claim 2, further comprising a control unit configured to control a temperature of the heated selenium and a flow rate of the carrier gas to generate a selected average particle size of the CIG powder particles.

9. The system of claim 1, wherein the carrier gas source comprises an inert gas source.

10. A method, comprising:
providing a molten stream of a metal material to an atomizer;
atomizing the molten stream using at least one jet of a vapor stream comprising a selenium vapor to form atomized droplets; and
solidifying the atomized droplets to form selenized metal particles.

11. The method of claim 10, further comprising:
vaporizing selenium in a vapor source to form the selenium vapor;
providing a carrier gas to the vapor source, such that the selenium vapor mixes with the carrier gas to form the vapor stream; and
providing the vapor stream from the vapor source to the atomizer to form the at least one jet of the vapor stream.

12. The method of claim 11, wherein:
the metal material comprises a copper indium gallium (CIG) alloy;
the atomized droplets comprise CIG droplets which cool and solidify to form CIG powder particles in a collection chamber;
the atomizer comprises a manifold containing a plurality of nozzles which direct jets of the vapor stream into the molten stream such that the selenium vapor reacts with CIG powder particles and forms a selenium-containing coating on the CIG powder particles; and
the selenized metal particles comprise selenized CIG powder particles.

13. The method of claim 12, wherein the manifold comprises:
an opening which receives the molten stream;
an annular internal chamber surrounding the opening which receives the vapor stream; and
the plurality of nozzles fluidly connected to the internal chamber.

14. The method of claim 13, wherein:
the vapor source comprises a furnace or evaporator which heats the selenium to a liquid state to generate the selenium vapor in a headspace above the heated liquid selenium; and
the carrier gas flows through headspace, and from the headspace into the annular internal chamber of the manifold through a distribution conduit.

15. The method of claim 14, wherein the plurality of nozzles direct the jets toward the molten stream at an acute angle with respect to a flow direction of the molten stream.

16. The method of claim 14, further comprising heating the distribution conduit to a higher temperature than the manifold to substantially prevent condensation of the selenium vapor.

17. The method of claim 14, further comprising using a mass flow sensor to control a flow rate of the carrier gas, wherein the carrier gas comprises an inert gas.

18. The method of claim 12, further comprising collecting the selenized CIG powder particles and providing the selenized CIG powder particles to a sputtering target to form a selenized CIG sputtering layer of the sputtering target.

19. The method of claim 18, wherein providing the selenized CIG powder particles to the sputtering target comprises cold spraying the selenized CIG powder particles over a backing structure of the sputtering target to form the selenized CIG sputtering layer of the sputtering target.

20. The method of claim 18, further comprising reactively sputtering the selenized CIG sputtering layer in a selenium containing ambient to form a copper indium gallium selenide absorber layer of a solar cell.
